(19) United States
(12) Patent Application Publication
(10) Pub. No.: US 2010/0132791 A1
(43) Pub. Date: Jun. 3, 2010

(54) HIGH EFFICIENCY SOLAR CELL, METHOD OF FABRICATING THE SAME AND APPARATUS FOR FABRICATING THE SAME

(75) Inventor: Jae-Ho Kim, Gyeonggi-do (KR)

Correspondence Address: HOSOON LEE, 9600 SW OAK ST. SUITE 525, TIGARD, OR, 97223, US

(73) Assignee: JUSUNG ENGINEERING CO., LTD., Gyeonggi-do (KR)

(21) Appl. No.: 12/597,497

(22) PCT Filed: May 29, 2008
(86) PCT No.: PCT/KR08/02999

§ 371 Date: Oct. 25, 2009

(30) Foreign Application Priority Data
May 29, 2007 (KR) 10-2007-0051829

(51) Int. Cl. H01L 31/0248; H01L 31/18; H01L 31/042; H01L 31/0216; H01L 31/0384

(52) U.S. Cl. 136/258; 438/96; 29/25.01; 438/72; 257/E31.12; 257/E31.047

(57) ABSTRACT

A method of fabricating a solar cell includes: sequentially forming a first electrode and a first impurity-doped semiconductor layer on a transparent substrate; forming a first intrinsic semiconductor layer on the first impurity-doped semiconductor layer; heating the first intrinsic semiconductor layer to form a second intrinsic semiconductor layer; and sequentially forming a second impurity-doped semiconductor layer and a second electrode on the second intrinsic semiconductor layer.

### TECHNICAL FIELD

The present invention relates to a solar cell, and more particularly, to a high efficiency solar cell including an intrinsic semiconductor layer of gradually varying crystallinity, a method of fabricating the solar cell and an apparatus for fabricating the solar cell.

### BACKGROUND ART

As concerns about clean energy such as solar power for coping with exhaust of fossil resources and environmental pollution increase, a solar cell generating an electromotive force using sunlight has been the subject of recent research.

Solar cells generate an electromotive force from diffusion of minority carriers, which are excited by sunlight, in P-N (positive-negative) junction layer. Single crystalline silicon, polycrystalline silicon, amorphous silicon or compound semiconductor may be used for the solar cells.

Although solar cells using single crystalline silicon or polycrystalline silicon have a relatively high energy-converting efficiency, solar cells using single crystalline silicon or polycrystalline silicon have a relatively high material cost and a relatively complicated fabrication process. Accordingly, a thin film type solar cell using amorphous silicon or compound semiconductor on a cheap substrate such as glass or plastic has been widely researched and developed. Specifically, a thin film type solar cell has advantages in a large-sized substrate and a flexible substrate so that a flexible large-sized solar cell can be produced.

FIG. 1 is a cross-sectional view of an amorphous silicon thin film type solar cell according to the related art. In FIG. 1, a front electrode 12, a semiconductor layer 13 and a rear electrode 14 are sequentially formed on a substrate 11. The transparent substrate 11 includes glass or plastic. The front electrode 12 includes a transparent conductive oxide (TCO) material for transmission of incident light from the transparent substrate 11. The semiconductor layer 13 includes amorphous silicon (a-Si:H). In addition, the semiconductor layer 13 includes a p-type semiconductor layer 13a, an intrinsic semiconductor layer 13b and an n-type semiconductor layer 13c sequentially on the front electrode 12, which form a PIN (positive-intrinsic-negative) junction layer. The intrinsic semiconductor layer 13b, which may be referred to as an active layer, functions as a light absorption layer increasing efficiency of the thin film type solar cell. The rear electrode 14 includes a TCO material or a metallic material such as aluminum (Al), copper (Cu) and silver (Ag).

When sunlight is irradiated onto the transparent substrate 11, minority carriers diffusing across the PIN junction layer of the semiconductor layer 13 on the transparent substrate 11 generate a voltage difference between the front electrode 12 and the rear electrode 14, thereby generating an electromotive force.

The amorphous silicon thin film type solar cell has a relatively low energy-converting efficiency as compared with a single crystalline silicon solar cell or a poly-crystalline silicon solar cell. In addition, as the amorphous silicon thin film type solar cell is exposed to light for a longer time period, the efficiency is further reduced according to a property-deterioration phenomenon, which is referred to as Staebler-Wronski effect.

To solve the above problems, a thin film type solar cell using microcrystalline silicon (μc-Si:H or mc-Si:H) instead of amorphous silicon has been suggested. The microcrystalline silicon as an intermediate material between amorphous silicon and single crystalline silicon has a grain size of several tens nano meters (nm) to several hundreds nm. In addition, the microcrystalline silicon does not have a property-deterioration phenomenon of amorphous silicon.

The intrinsic semiconductor layer of microcrystalline silicon has a thickness of about 1 μm to about 3 μm because of lower absorption coefficient of light, while the intrinsic semiconductor layer of amorphous silicon has a thickness of about 200 nm to about 500 nm. In addition, since a deposition rate of microcrystalline silicon is lower than a deposition rate of amorphous silicon layer, thicker microcrystalline silicon is much lower productivity than thinner amorphous silicon.

Furthermore, a band gap of amorphous silicon is about 1.7 eV to about 1.8 eV, while a band gap of microcrystalline silicon is about 1.1 eV, which is the same as a band gap of single crystalline silicon. Accordingly, amorphous silicon and microcrystalline silicon have difference in light absorption property. As a result, amorphous silicon absorbs light having a wavelength mostly of about 350 nm to about 800 nm, while microcrystalline silicon absorbs light having a wavelength mostly of about 350 nm to about 1200 nm. Recently, a solar cell of a tandem (double) structure or a triple structure where PIN junction layers of amorphous silicon and microcrystalline silicon are sequentially formed has been widely used on the basis of the difference in light absorption property between amorphous silicon and microcrystalline silicon. For example, when a first PIN junction layer of amorphous silicon that absorbs light mostly in a shorter wavelength band is formed on a transparent substrate onto which sunlight is irradiated and a second PIN junction layer of microcrystalline silicon that absorbs light mostly in a longer wavelength band is formed on the first PIN junction layer of amorphous silicon, light absorption of the first and second PIN junction layers is improved, thereby improving energy-converting efficiency.

### DISCLOSURE OF INVENTION

### Technical Problem

Although the solar cell of a tandem structure or a triple structure has advantages in energy-converting efficiency as compared with a solar cell of a single structure of amorphous silicon or microcrystalline silicon, the solar cell of a tandem structure or a triple structure still has a relatively complicated fabrication process. Moreover, since the fabrication process for the solar cell of a tandem structure or a triple structure includes a deposition step of microcrystalline silicon, there exists a limitation in improvement of productivity.

### Technical Solution

Accordingly, the present invention is directed to a solar cell, a method of fabricating the solar cell and an apparatus for the solar cell that substantially obviate one or more of the problems due to limitations and disadvantages of the related art.

An object of the present invention is to provide a high efficiency solar cell having a simplified fabrication process and an improved productivity, a method of fabricating the solar cell and an apparatus for the solar cell.

Another object of the present invention is to provide a high efficiency solar cell using microcrystalline silicon and amorphous silicon as a light absorbing layer, a method of fabricating the solar cell and an apparatus for the solar cell.

A method of fabricating a high efficiency solar cell includes: sequentially forming a first electrode and a first impurity-doped semiconductor layer on a transparent substrate; forming a first intrinsic semiconductor layer on the first impurity-doped semiconductor layer; heating the first intrinsic semiconductor layer to form a second intrinsic semiconductor layer; and sequentially forming a second impurity-doped semiconductor layer and a second electrode on the second intrinsic semiconductor layer.

In another aspect, a high efficiency solar cell includes: a transparent substrate; a first electrode on the transparent substrate; a first impurity-doped semiconductor layer on the first electrode; an intrinsic semiconductor layer on the first impurity-doped semiconductor layer, the intrinsic semiconductor layer having a gradually varying crystallinity; a second impurity-doped semiconductor layer on the intrinsic semiconductor layer; and a second electrode on the second impurity-doped semiconductor layer.

In another aspect, an apparatus for fabricating a solar includes: a transfer chamber including a transfer means for transferring a substrate; a load lack chamber coupled with a first side portion of the transfer chamber, the load lack chamber alternately having a vacuum state and an atmospheric pressure state for inputting and outputting the substrate; a first process chamber coupled with a second side portion of the transfer chamber, the first process chamber forming a first impurity-doped semiconductor layer on a first electrode on the substrate; a second process chamber coupled with a third side portion of the transfer chamber, the second process chamber forming a first intrinsic semiconductor layer on the first impurity-doped semiconductor layer; a third process chamber coupled with a fourth side portion of the transfer chamber, the third process chamber heating the first intrinsic semiconductor layer to form a second intrinsic semiconductor layer having a gradually varying crystallinity; and a fourth process chamber coupled with a fifth side portion of the transfer chamber, the fourth process chamber forming a second impurity-doped semiconductor layer on the second intrinsic semiconductor layer.

In another aspect, an apparatus for fabricating a solar includes: a loading chamber alternately having a vacuum state and an atmospheric pressure state for inputting a substrate; a first process chamber coupled with a side portion of the loading chamber, the first process chamber forming a first impurity-doped semiconductor layer on a first electrode on the substrate; a second process chamber coupled with a side portion of the first process chamber, the second process chamber forming a first intrinsic semiconductor layer on the first impurity-doped semiconductor layer; a third process chamber coupled with a side portion of the second process chamber, the third process chamber heating the first intrinsic semiconductor layer to form a second intrinsic semiconductor layer having a gradually varying crystallinity; a fourth process chamber coupled with a side portion of the third process chamber, the fourth process chamber forming a second impurity-doped semiconductor layer on the second intrinsic semiconductor layer; and an unloading chamber coupled with a side portion of the fourth process chamber, the unloading chamber alternately having a vacuum state and an atmospheric pressure state for outputting the substrate.

In another aspect, a method of fabricating a solar cell includes: sequentially forming a first electrode and a first impurity-doped semiconductor layer on a transparent substrate; forming a light absorbing layer on the first impurity-doped semiconductor layer; heating the light absorbing layer; and sequentially forming a second impurity-doped semiconductor layer and a second electrode on the light absorbing layer.

In another aspect, a method of fabricating a solar cell includes: sequentially forming a first electrode and a first impurity-doped semiconductor layer on a transparent substrate; forming a first intrinsic semiconductor layer on the first impurity-doped semiconductor layer; crystallizing the first intrinsic semiconductor layer to form a second intrinsic semiconductor layer having a gradually varying crystallinity; and sequentially forming a second impurity-doped semiconductor layer and a second electrode on the second intrinsic semiconductor layer.

### ADVANTAGEOUS EFFECTS

In a high efficiency solar cell according to an embodiment of the present invention, since an intrinsic semiconductor layer of linearly crystallized silicon used as a light absorbing layer includes amorphous silicon and microcrystalline silicon, light absorption band is broaden and energy-converting efficiency is improved. In addition, since a separate step of forming a microcrystalline silicon layer that has a relatively low deposition rate is omitted, a fabrication process for a high efficiency solar cell according to an embodiment of the present invention is simplified as compared with a fabrication process for a tandem structure solar cell or a triple structure solar cell. As a result, productivity is improved.

### BRIEF DESCRIPTION OF THE DRAWINGS

The accompanying drawings, which are included to provide a further understanding of the invention and are incorporated in and constitute a part of this specification, illustrate embodiments of the invention.

FIG. 1 is a cross-sectional view of an amorphous silicon thin film type solar cell according to the related art

FIG. 2 is a flow chart showing a fabrication process of a solar cell according to an embodiment of the present invention;

FIGS. 3 to 7 are cross-sectional views showing a fabrication process of a solar cell according to an embodiment of the present invention;

FIG. 8 is a cross-sectional view showing a RTP for a solar cell according to another embodiment of the present invention;

FIG. 9 is a plan views showing a cluster type apparatus for a solar cell according to an embodiment of the present invention; and

FIG. 10 is a plan views showing an in-line type apparatus for a solar cell according to an embodiment of the present invention.

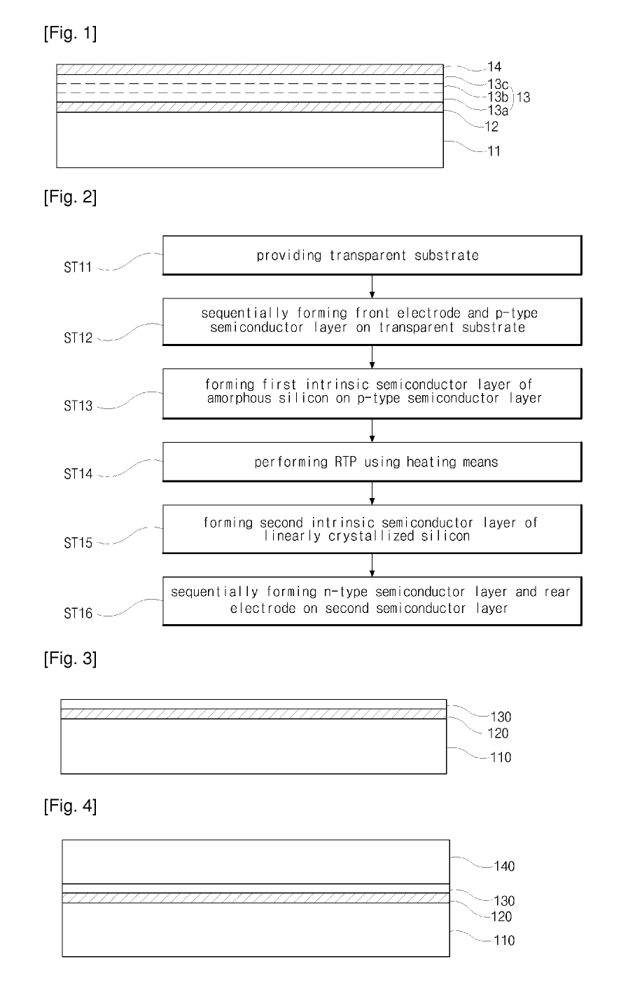

### MODE FOR THE INVENTION

Reference will now be made in detail to embodiments which are illustrated in the accompanying drawings. Wherever possible, similar reference numbers will be used to refer to the same or similar parts.

FIG. 2 is a flow chart showing a fabrication process of a solar cell according to an embodiment of the present invention, and FIGS. 3 to 7 are cross-sectional views showing a fabrication process of a solar cell according to an embodiment of the present invention.

At steps of ST11 and ST12 and in FIG. 3, a transparent substrate 110 is provided, and a front electrode 120 (i.e., a first electrode) and a p-type semiconductor layer (i.e., a first impurity-doped semiconductor layer) of amorphous silicon 130 are sequentially formed on the transparent substrate 110. The front electrode 120 includes a transparent conductive oxide (TCO) material for transmission of incident light from the transparent substrate 110. For example, the front electrode 120 may have a thickness of about 700 nm to about 2000 nm. The p-type semiconductor layer 130 of amorphous silicon may have a thickness of about 30 nm. For example, the p-type semiconductor layer 130 of amorphous silicon may be formed by a plasma enhanced chemical vapor deposition (PECVD) method using SiH₄, H₂, B₂H₆ and CH₄.

At step of ST13 and in FIG. 4, a first intrinsic semiconductor layer 140 of amorphous silicon is formed on the p-type semiconductor layer 130 of amorphous silicon. The first intrinsic semiconductor layer 140 of amorphous silicon functions as a light absorbing layer and may have a thickness of about 1 μm to about 3 μm. For example, the first intrinsic semiconductor layer 140 of amorphous silicon may be formed by a PECVD method using SiH₄ and H₂.

Although not shown at step of ST13 and in FIG. 4, a buffer layer may be formed between the p-type semiconductor layer 130 and the first intrinsic semiconductor layer 140 in order to eliminate interface defects and adjust band gap levels. For example, the buffer layer may include a thin layer of microcrystalline silicon or amorphous silicon.

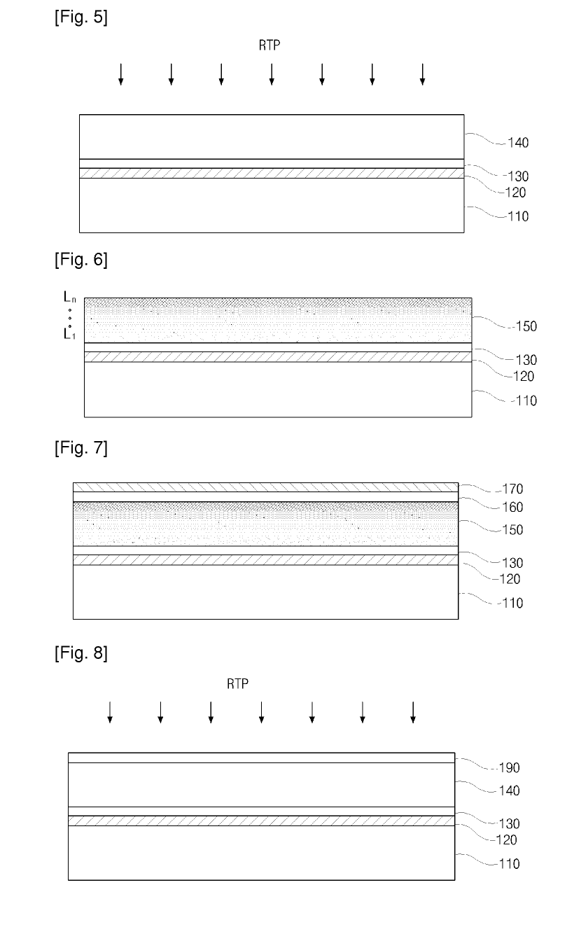

At step of ST 14 and in FIG. 5, a rapid thermal process (RTP) is performed for the first intrinsic semiconductor layer 140 of amorphous silicon. For example, after the transparent substrate 110 including the first intrinsic semiconductor layer 140 of amorphous silicon is transferred into a heating chamber, the first intrinsic semiconductor layer 140 of amorphous silicon is heated up to about 500° C. to about 600° C. for a predetermined time period under a hydrogen (H₂) ambient using a heating means such as a xenon (Xe) lamp or a halogen lamp applying heat optically. The predetermined time period for heating may be within a range of several minutes to several tens minutes. The first intrinsic semiconductor layer of amorphous silicon is not completely crystallized by the RTP. Instead, the first intrinsic semiconductor layer 140 of amorphous silicon is heated such that about 30% to about 40% of the whole amorphous silicon of the first intrinsic semiconductor layer 140 is crystallized by the RTP.

At step of ST 15 and in FIG. 6, the first intrinsic semiconductor layer 140 of amorphous silicon is crystallized by the RTP to form a second intrinsic semiconductor layer 150 of linearly crystallized silicon. The second intrinsic semiconductor layer 150 has a gradually varying crystallinity along a vertical direction perpendicular to the transparent substrate 110. Accordingly, a portion of the second intrinsic semiconductor layer 150 closer to the heating means has higher crystallinity than a portion of the second intrinsic semiconductor layer 150 farther from the heating means. As a result, the crystallinity of the second intrinsic semiconductor layer 150 is proportional to a distance from a bottom surface of the second intrinsic semiconductor layer 150. For example, the crystallinity of the second intrinsic semiconductor layer 150 may linearly increase along a direction from a bottom surface adjacent to the transparent substrate 110 to a top surface adjacent to the heating means. As a result, the second intrinsic semiconductor layer 150 of linearly crystallized silicon has a linearly increasing crystallinity from the bottom surface contacting the p-type semiconductor layer 130 to the top surface adjacent to the heating means. For example, a portion near the bottom surface contacting the p-type semiconductor layer 130 may have amorphous silicon and a portion near the top surface adjacent to the heating means may have microcrystalline silicon.

For illustration, the second intrinsic semiconductor layer 150 may be classified into first to n^{th} very thin layers L1 to Ln having first to n^{th} crystallinities Xc(1) to Xc(n), respectively. The first to nth crystallinities Xc(1) to Xc(n) satisfy a following equation 1.

Xc(n)>Xc(n−1)> . . . >Xc(2)>Xc(1) equation 1

Accordingly, when the first to nth crystallinities Xc(1) to Xc(n) have first to n^{th} band gaps Bg(1) to Bg(n), respectively, the first to n^{th} band gaps Bg(1) to Bg(n) satisfy a following equation 2.

Bg(n)<Bg(n−1)< . . . <Bg(2)<Bg(1) equation 2

, where the n^{th} band gap Bg(n) is a band gap of microcrystalline silicon having about 1.1 eV and the first band gap Bg(1) is a band gap of amorphous silicon within a range of about 1.7 eV to about 1.8 eV.

Although the solar cell according to an embodiment of the present invention does not include PIN junction layers of amorphous silicon and PIN junction layers of microcrystalline silicon of a tandem structure or a triple structure as an absorption layer, the light absorption band of the solar cell is broadened to cover a range from a shorter wavelength band to a longer wavelength band because the second intrinsic semiconductor layer has a continuous distribution of crystallinity, e.g., from amorphous silicon to microcrystalline silicon.

FIG. 8 is a cross-sectional view showing a RTP for a solar cell according to another embodiment of the present invention.

In FIG. 8, a metal layer 190 is formed on the first intrinsic semiconductor layer 140 of amorphous silicon for reducing a temperature of an RTP and increasing a speed of crystallization. The metal layer 190 may include at least one of nickel (Ni), aluminum (Al) and palladium (Pd). Next, the RTP is performed for the metal layer 190 and the first intrinsic semiconductor layer 140 of amorphous silicon using a heating means such as a xenon (Xe) lamp or a halogen lamp applying heat optically. While the RTP is performed, metallic materials of the metal layer 190 are diffused into the first intrinsic semiconductor layer 140 to form a metal silicide. Since the metal silicide functions as a crystalline nucleus in crystallization by the RTP, the first intrinsic semiconductor layer 140 is crystallized under a relatively low temperature of about 350° C. to about 450° C. to form a second intrinsic semiconductor layer of linearly crystallized silicon. In addition, since the first intrinsic semiconductor layer 140 is crystallized by the RTP for a relatively shorter predetermined time period due to function of the metal silicide, the speed of crystallization increases. Specifically, the RTP with a metal layer may be advantageously applied to a fabrication method for a solar cell including a transparent substrate of plastic having a relatively low heat resistance. After the RTP, the metal layer may remain and be used as a portion of electrode, or may be removed from the second intrinsic semiconductor layer.

At step of ST16 and FIG. 7, an n-type semiconductor layer (i.e., second impurity-doped semiconductor layer) of amorphous silicon and a rear electrode 170 (i.e., second electrode) are sequentially formed on the second intrinsic semiconductor layer 150 of linearly crystallized silicon. The n-type semiconductor layer 160 of amorphous silicon may have a thickness of about 50 nm. For example, the n-type semiconductor layer 160 of amorphous silicon may be formed by a PECVD method using SiH₄, H₂ and PH₃. The rear electrode 170 may include a TCO material or one of aluminum (Al), copper (Cu) and silver (Ag).

When sunlight corresponding to a broad wavelength band is irradiated onto the transparent substrate 110 of the solar cell, the second intrinsic semiconductor layer 150 of linearly crystallized silicon absorbs the sunlight through the p-type semiconductor layer 130. Since a portion of the second intrinsic semiconductor layer 150 adjacent to an interface with the p-type semiconductor layer 130 has a lower crystallinity, i.e., a higher ratio of amorphous silicon, the portion of the second intrinsic semiconductor layer 150 adjacent to the interface with the p-type semiconductor layer 130 absorbs the sunlight mostly corresponding to a shorter wavelength band. In addition, since a portion of the second intrinsic semiconductor layer 150 adjacent to an interface with the n-type semiconductor layer 160 has a higher crystallinity, i.e., a higher ratio of microcrystalline silicon, the portion of the second intrinsic semiconductor layer 150 adjacent to the interface with the n-type semiconductor layer 160 absorbs the sunlight mostly corresponding to a longer wavelength band. Accordingly, light absorption and energy-converting efficiency of the solar cell according to an embodiment of the present invention are improved.

FIGS. 5 and 6 are plan views showing a cluster type apparatus and an in-line type apparatus, respectively, for a solar cell according to an embodiment of the present invention.

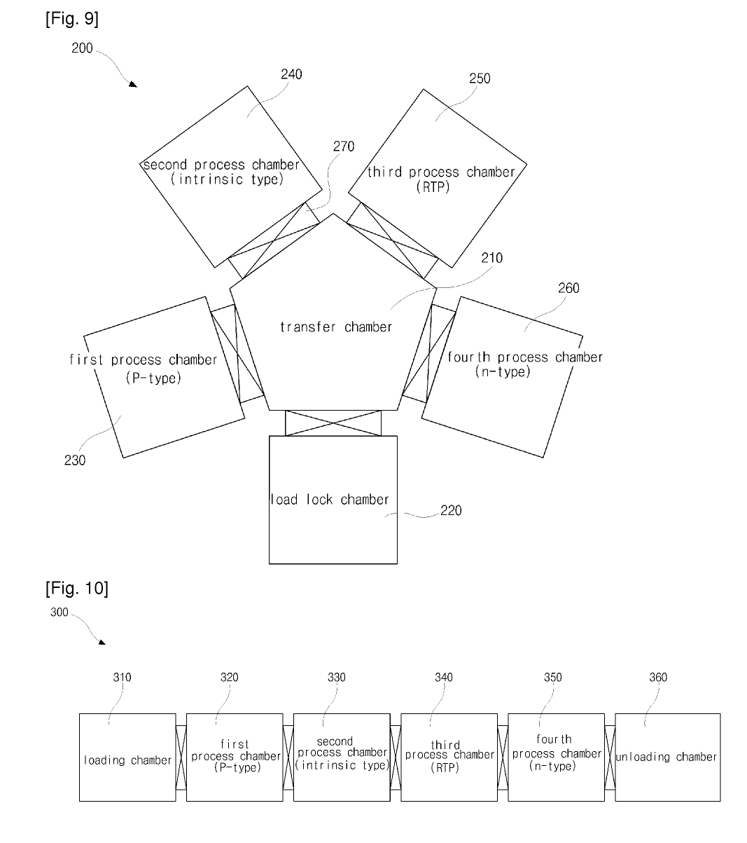

In FIG. 9, a cluster type apparatus 200 for a solar cell includes a transfer chamber 210, a load lack chamber 220 and a plurality of process chambers, e.g., first to fourth process chambers 233 to 260. The load lack chamber 220 and the first to fourth process chambers 233 to 260 surround and are coupled with the transfer chamber 210. The transfer chamber 210 may include a transfer means such as a robot (not shown) therein to transfer a substrate between chambers. The transfer chamber 210 maintains a vacuum state during the fabrication process of the solar cell. The load lack chamber 220 is used as a buffer space for transferring a substrate between the transfer chamber 210 under a vacuum state and an exterior under an atmospheric pressure state. Accordingly, the load lack chamber 220 alternately has a vacuum state and an atmospheric pressure state.

For example, the first to fourth process chambers 230 to 260 are coupled with side portions of the transfer chamber 210. The p-type semiconductor layer 130 (of FIG. 3) is formed on the transparent substrate 110 (of FIG. 3) in the first process chamber 230, and the first intrinsic semiconductor layer 140 (of FIG. 4) of amorphous silicon is formed on the p-type semiconductor layer 130 in the second process chamber 240. In addition, the first intrinsic semiconductor layer 140 is crystallized by the RTP to become the second intrinsic semiconductor layer 150 (of FIG. 6) of linearly crystallized silicon in the third process chamber 250, and the n-type semiconductor layer 160 (of FIG. 7) is formed on the second intrinsic semiconductor layer 150 in the fourth process chamber 260. A slot valve 270 selectively opening and closing a substrate path is disposed between the transfer chamber 210 and each of the load lack chamber 220 and the first to fourth process chambers 230 to 260

After the transparent substrate 110 having the front electrode 120 thereon is inputted into the load lack chamber 220, the load lack chamber 220 is evacuated to have a vacuum state predetermined pressure. Next, the slot valve 270 between the load lack chamber 220 and the transfer chamber 210 is opened and the transparent substrate 110 is transferred from the load lack chamber 220 to the first process chamber 230 through the transfer chamber 210 by the transfer robot. In the first process chamber 230, the p-type semiconductor layer 130 is formed on the front electrode 120. The first intrinsic semiconductor layer 140 is formed on the p-type semiconductor layer 130 after the transparent substrate 110 is transferred to the second process chamber 240, and the first intrinsic semiconductor layer 140 is crystallized to become the second intrinsic semiconductor layer 150 after the transparent substrate 110 is transferred to the third process chamber 250. Similarly, the n-type semiconductor layer 160 is formed on the second intrinsic semiconductor layer 150 after the transparent substrate 110 is transferred to the fourth process chamber 260. Next, the transparent substrate 110 is transferred from the fourth process chamber 260 to the load lack chamber 220 through the transfer chamber 210, and the transparent substrate 110 having the front electrode 120, the p-type semiconductor layer 130, the second intrinsic semiconductor layer 150 and the n-type semiconductor layer 160 thereon is outputted from the load lack chamber 220

In FIG. 10, an in-line type apparatus 300 for a solar cell includes a loading chamber 310, first to fourth process chambers 320 to 350 and an unloading chamber 360. The loading chamber 310, the first to fourth process chambers 320 to 350 and the unloading chamber 360 are serially coupled with each other. A substrate is inputted into the loading chamber 310 and outputted from the unloading chamber 360. Each of the loading chamber 310, the first to fourth process chambers 320 to 350 and the unloading chamber 360 includes an in-line type transferring means such as a roller or a linear motor to transfer a substrate. The first to fourth process chambers 320 to 350 maintains a vacuum state during the fabrication process of the solar cell. Since a substrate is transferred between an exterior under an atmospheric pressure state and each of the first and fourth process chambers 320 and 350, each of the loading chamber 310 and the unloading chamber 360 alternately has a vacuum state and an atmospheric pressure state.

After the transparent substrate 110 (of FIG. 3) having the front electrode 120 (of FIG. 3) thereon is transferred to the first process chamber 320, the p-type semiconductor layer 133 (of FIG. 3) is formed on the front electrode 120. The first intrinsic semiconductor layer 140 (of FIG. 4) is formed on the p-type semiconductor layer 130 after the transparent substrate 110 is transferred to the second process chamber 330, and the first intrinsic semiconductor layer 140 is crystallized to become the second intrinsic semiconductor layer 150 (of FIG. 6) after the transparent substrate 110 is transferred to the third process chamber 340. Similarly, the n-type semiconductor layer 160 (of FIG. 7) is formed on the second intrinsic semiconductor layer 150 after the transparent substrate 110 is transferred to the fourth process chamber 350. After the transparent substrate 110 having the front electrode 120, the p-type semiconductor layer 130, the second intrinsic semiconductor layer 150 and the n-type semiconductor layer 160 thereon is outputted from the in-line type apparatus for a solar cell, the rear electrode 170 (of FIG. 7) may be formed on the n-type semiconductor layer 160 in another apparatus such as a sputter.

It will be apparent to those skilled in the art that various modifications and variations can be made in a solar cell, a method of fabricating the solar cell and an apparatus for fabricating the solar cell of the present invention without departing from the spirit or scope of the invention. Thus, it is intended that the present invention cover the modifications and variations of this invention provided they come within the scope of the appended claims and their equivalents.

1. A method of fabricating a solar cell, comprising:
sequentially forming a first electrode and a first impurity-doped semiconductor layer on a transparent substrate;
forming a first intrinsic semiconductor layer on the first impurity-doped semiconductor layer;
heating the first intrinsic semiconductor layer to form a second intrinsic semiconductor layer; and
sequentially forming a second impurity-doped semiconductor layer and a second electrode on the second intrinsic semiconductor layer.

2. The method according to claim 1, wherein the second intrinsic semiconductor layer includes a linearly crystallized silicon such that a crystallinity of the second intrinsic semiconductor layer linearly varies along a direction from a bottom surface to a top surface of the second intrinsic semiconductor layer.

3. The method according to claim 1, wherein the first intrinsic semiconductor layer has a thickness of about 1 μm to about 3 μm.

4. The method according to claim 1, wherein a first portion of the second intrinsic semiconductor layer closer to the first impurity-doped semiconductor layer has a higher crystallinity and a second portion of the second intrinsic semiconductor layer closer to the second impurity-doped semiconductor layer has a lower crystallinity.

5. The method according to claim 1, wherein a first portion of the second intrinsic semiconductor layer closer to the first impurity-doped semiconductor layer has a higher band gap and a second portion of the second intrinsic semiconductor layer closer to the second impurity-doped semiconductor layer has a lower band gap.

6. The method according to claim 1, wherein heating the first intrinsic semiconductor layer comprises:
disposing an optical heating means over the first intrinsic semiconductor layer;
irradiating light onto the first intrinsic semiconductor layer; and
heating the first intrinsic semiconductor layer up to about 500° C. to about 600° C.

7. The method according to claim 1, wherein heating the first intrinsic semiconductor layer comprises:
forming a metal layer on the first intrinsic semiconductor layer;
disposing an optical heating means over the metal layer;
irradiating light onto the metal layer; and
heating the first intrinsic semiconductor layer up to about 350° C. to about 450° C.

8. The method according to claim 7, wherein the metal layer includes at least one of nickel (Ni), aluminum (Al) and palladium (Pd).

9. The method according to claim 1, wherein the first impurity-doped semiconductor layer includes a p-type amorphous silicon, the first intrinsic semiconductor layer includes an intrinsic amorphous silicon, and the second impurity-doped semiconductor layer includes an n-type amorphous silicon.

10. A high efficiency solar cell, comprising:
a transparent substrate;
a first electrode on the transparent substrate;
a first impurity-doped semiconductor layer on the first electrode;
an intrinsic semiconductor layer on the first impurity-doped semiconductor layer,
the intrinsic semiconductor layer having a gradually varying crystallinity;
a second impurity-doped semiconductor layer on the intrinsic semiconductor layer; and
a second electrode on the second impurity-doped semiconductor layer.

11. The solar cell according to claim 10, wherein the intrinsic semiconductor layer includes a linearly crystallized silicon such that a crystallinity of the intrinsic semiconductor layer linearly varies along a direction from a bottom surface to a top surface of the intrinsic semiconductor layer.

12. The solar cell according to claim 10, further comprising a metal layer between the intrinsic semiconductor layer and the second impurity-doped semiconductor layer.

13. An apparatus for fabricating a solar, comprising:
a transfer chamber including a transfer means for transferring a substrate;
a load lack chamber coupled with a first side portion of the transfer chamber, the load lack chamber alternately having a vacuum state and an atmospheric pressure state for inputting and outputting the substrate;
a first process chamber coupled with a second side portion of the transfer chamber, the first process chamber forming a first impurity-doped semiconductor layer on a first electrode on the substrate;
a second process chamber coupled with a third side portion of the transfer chamber, the second process chamber forming a first intrinsic semiconductor layer on the first impurity-doped semiconductor layer;
a third process chamber coupled with a fourth side portion of the transfer chamber, the third process chamber heating the first intrinsic semiconductor layer to form a second intrinsic semiconductor layer having a gradually varying crystallinity; and
a fourth process chamber coupled with a fifth side portion of the transfer chamber, the fourth process chamber forming a second impurity-doped semiconductor layer on the second intrinsic semiconductor layer.

14. An apparatus for fabricating a solar, comprising:
a loading chamber alternately having a vacuum state and an atmospheric pressure state for inputting a substrate;
a first process chamber coupled with a side portion of the loading chamber, the first process chamber forming a first impurity-doped semiconductor layer on a first electrode on the substrate;
a second process chamber coupled with a side portion of the first process chamber, the second process chamber forming a first intrinsic semiconductor layer on the first impurity-doped semiconductor layer;
a third process chamber coupled with a side portion of the second process chamber, the third process chamber heating the first intrinsic semiconductor layer to form a second intrinsic semiconductor layer having a gradually varying crystallinity;
a fourth process chamber coupled with a side portion of the third process chamber, the fourth process chamber forming a second impurity-doped semiconductor layer on the second intrinsic semiconductor layer; and
an unloading chamber coupled with a side portion of the fourth process chamber, the unloading chamber alternately having a vacuum state and an atmospheric pressure state for outputting the substrate.

15. A method of fabricating a solar cell, comprising:
sequentially forming a first electrode and a first impurity-doped semiconductor layer on a transparent substrate;
forming a light absorbing layer on the first impurity-doped semiconductor layer;
heating the light absorbing layer; and
sequentially forming a second impurity-doped semiconductor layer and a second electrode on the light absorbing layer.

16. A method of fabricating a solar cell, comprising:
sequentially forming a first electrode and a first impurity-doped semiconductor layer on a transparent substrate;
forming a first intrinsic semiconductor layer on the first impurity-doped semiconductor layer;
crystallizing the first intrinsic semiconductor layer to form a second intrinsic semiconductor layer having a gradually varying crystallinity; and
sequentially forming a second impurity-doped semiconductor layer and a second electrode on the second intrinsic semiconductor layer.
